(19) United States
(12) Patent Application Publication
(10) Pub. No.: US 2024/0085355 A1
(43) Pub. Date: Mar. 14, 2024

(54) MEASURING METHOD AND MEASURING DEVICE

(71) Applicant: Japan Display Inc., Tokyo (JP)

(72) Inventor: Satoru TOMITA, Tokyo (JP)

(73) Assignee: Japan Display Inc., Tokyo (JP)

(21) Appl. No.: 18/466,824

(22) Filed: Sep. 14, 2023

(30) Foreign Application Priority Data
Sep. 14, 2022 (JP) 2022-146452

(51) Int. Cl. G01N 23/2251

(52) U.S. Cl. CPC G01N 23/2251

(57) ABSTRACT

According to one embodiment, a measuring method includes forming a partition including a lower portion arranged on a base and an upper portion protruding from a side surface of the lower portion, acquiring a first image generated by detecting a secondary electron generated by emitting an electron beam including a primary electron to an area including at least a part of the side surface of the lower portion and at least a part of an end portion of the upper portion, analyzing the first image, and measuring an amount of protrusion by which the end portion of the upper portion protrudes from the side surface of the lower portion, based on the analysis result.

### CROSS-REFERENCE TO RELATED APPLICATIONS

This application is based upon and claims the benefit of priority from Japanese Patent Application No. 2022-146452, filed Sep. 14, 2022, the entire contents of which are incorporated herein by reference.

### FIELD

Embodiments described herein relate generally to a measuring method and a measuring device.

### BACKGROUND

Recently, display devices with organic light-emitting diodes (OLEDs) applied thereto as display elements have been put into practical use.

Incidentally, the display device described above is manufactured by preparing a motherboard on which a plurality of display panels are formed, and using each of the display panels cut from the motherboard.

A technique of suppressing the reduction in reliability has been required in a process of manufacturing such a display device.

### BRIEF DESCRIPTION OF THE DRAWINGS

FIG. 1 is a view showing a configuration example of a display device according to an embodiment.

FIG. 2 is a view showing an example of a layout of sub-pixels.

FIG. 3 is a schematic cross-sectional view showing the display device along line III-III in FIG. 2.

FIG. 4 is a schematic cross-sectional view showing a partition.

FIG. 5 is a schematic cross-sectional view illustrating a display element formed using a partition.

FIG. 6 is a schematic cross-sectional view illustrating the display element formed using the partition.

FIG. 7 is a schematic cross-sectional view illustrating the display element formed using the partition.

FIG. 8 is a view illustrating a motherboard inspection device used in a display device manufacturing process.

FIG. 9 is a view illustrating a configuration of SEM.

FIG. 10 is a view illustrating an example of an electron beam emitted to a partition.

FIG. 11 is a view showing an example of a hardware configuration of a measuring device.

FIG. 12 is a view showing an example of a functional configuration of the measuring device.

FIG. 13 is a flowchart showing an example of a processing procedure of the measuring device.

FIG. 14 is a view showing an example of a SEM image.

FIG. 15 is a view illustrating another example of the electron beam emitted to a partition.

FIG. 16 is a view schematically showing the motherboard.

FIG. 17 is a view illustrating another example of measuring an amount of protrusion of the partition.

### DETAILED DESCRIPTION

In general, according to one embodiment, a measuring method includes forming a partition including a lower portion arranged on a base and an upper portion protruding from a side surface of the lower portion, acquiring a first image generated by detecting a secondary electron generated by emitting an electron beam including a primary electron to an area including at least a part of the side surface of the lower portion and at least a part of an end portion of the upper portion from a second direction inclined from a first direction perpendicular to the base, analyzing the acquired first image, and measuring an amount of protrusion by which the end portion of the upper portion protrudes from the side surface of the lower portion, based on the analysis result.

An embodiment will be described hereinafter with reference to the accompanying drawings.

The disclosure is merely an example, and proper changes within the spirit of the invention, which are easily conceivable by a person of ordinary skill in the art, are included in the scope of the invention as a matter of course. In addition, in some cases, in order to make the description clearer, the widths, thicknesses, shapes and the like, of the respective parts are schematically illustrated in the drawings, compared to the actual modes. However, the schematic illustration is merely an example, and adds no restriction to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis and a Z-axis orthogonal to each other are described to facilitate understanding as needed. A direction along the X-axis is referred to as a direction X, a direction along the Y-axis is referred to as a direction Y, and a direction along the Z-axis is referred to as a direction Z. In addition, viewing various elements parallel to the direction Z is referred to as plan view.

The display device of the embodiment is an organic electroluminescent display device including an organic light emitting diode (OLED) as a display element, and can be mounted on televisions, personal computers, vehicle-mounted devices, tablet terminals, smartphones, cellphone terminals, and the like.

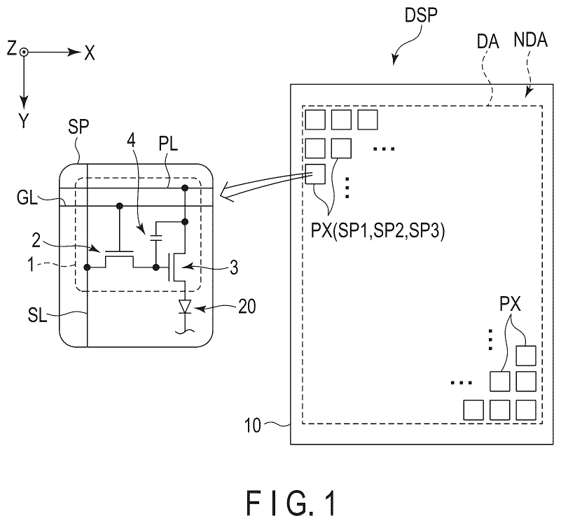

FIG. 1 is a view showing a configuration example of a display device DSP according to the embodiment. The display device DSP has a display area DA where images are displayed and a non-display area NDA around the display area DA, on an insulating base 10. The base 10 may be glass or a flexible resin film.

In the embodiment, a shape of the base 10 in plan view is a rectangular shape. However, the shape of the base 10 in plan view is not limited to a rectangular shape, but may also be other shape such as a square, a circle or an ellipse.

The display area DA includes a plurality of pixels PX arrayed in a matrix in the direction X and the direction Y. Each of the pixels PX includes a plurality of sub-pixels SP. As an example, the pixel PX includes a red sub-pixel SP1, a green sub-pixel SP2, and a blue sub-pixel SP3. The pixel PX may include a sub-pixel SP of the other color such as white, together with the sub-pixels SP1, SP2, and SP3. In addition, the pixel PX may include a sub-pixel SP of the other color instead of any of the sub-pixels SP1, SP2, and SP3.

The sub-pixel SP includes a pixel circuit 1 and a display element 20 driven by the pixel circuit 1. The pixel circuit 1 includes a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. Either of a source electrode and a drain electrode of the pixel switch 2 is connected to a signal line SL, and the other is connected to a gate electrode of the drive transistor 3, and the capacitor 4. In the drive transistor 3, either of the source electrode and the drain electrode is connected to a power line PL and the capacitor 4, and the other is connected to the display element 20.

The configuration of the pixel circuit 1 is not limited to the example shown in FIG. 1. For example, the pixel circuit 1 may include more thin-film transistors and capacitors.

The display element 20 is an organic light emitting diode (OLED) serving as a light emitting element. For example, the sub-pixel SP1 includes a display element 20 that emits light of a red wavelength range, the sub-pixel SP2 includes a display element 20 that emits light of a green wavelength range, and the sub-pixel SP3 includes a display element 20 that emits light of a blue wavelength range.

FIG. 1 mainly shows a display panel used for manufacturing the display device DSP, and the display device DSP has a structure in which a circuit board including a driver (driver IC chip) which drives the display panel and the like are connected to the display panel.

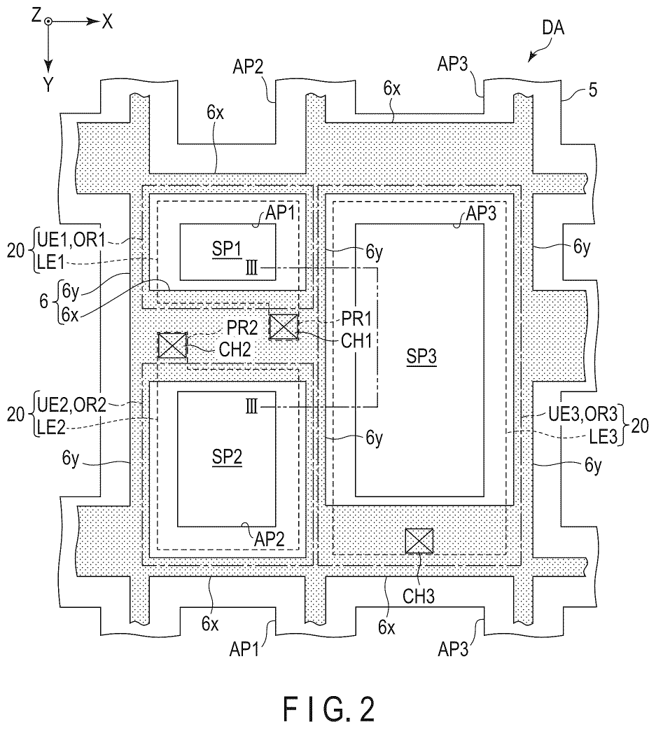

FIG. 2 shows an example of a layout of the sub-pixels SP1, SP2, and SP3. In the example shown in FIG. 2, the sub-pixels SP1 and SP2 are aligned in the direction Y. Furthermore, each of the sub-pixels SP1 and SP2 is arranged with the sub-pixel SP3 in the direction X.

When the sub-pixels SP1, SP2, and SP3 are arranged in the layout shown in FIG. 2, a row in which the sub-pixels SP1 and SP2 are alternately arranged in the direction Y and a row in which a plurality of sub-pixels SP3 are repeatedly arranged in the direction Y are formed in the display area DA. These rows are alternately arranged in the direction X.

The layout of the sub-pixels SP1, SP2, and SP3 is not limited to the example in FIG. 2. As another example, the sub-pixels SP1, SP2, and SP3 in each pixel PX may be arranged in order in the direction X.

A rib 5 and a partition 6 are arranged in the display area DA. The rib 5 includes apertures AP1, AP2, and AP3 in the sub-pixels SP1, SP2, and SP3, respectively. In the example shown in FIG. 2, the aperture AP2 is larger than the aperture AP1, and the aperture AP3 is larger than the aperture AP2. The partition 6 is arranged at the boundary between adjacent sub-pixels SP and overlaps with the rib 5 in plan view.

The partition 6 includes a plurality of first partitions 6x extending in the direction X and a plurality of second partitions 6y extending in the direction Y. The plurality of first partitions 6x are arranged between the apertures AP1 and AP2 adjacent in the direction Y and between two apertures AP3 adjacent in the direction Y. The second partitions 6y are arranged between the apertures AP1 and AP3 adjacent in the direction X and between the apertures AP2 and AP3 adjacent in the direction X.

In the example in FIG. 2, the first partitions 6x and the second partitions 6y are connected to each other. Thus, the partition 6 has a grating pattern surrounding the apertures AP1, AP2, and AP3 as a whole. The partition 6 is considered to include apertures at the sub-pixels SP1, SP2, and SP3, similarly to the rib 5.

In other words, in the embodiment, the rib 5 and the partition 6 are arranged to divide the sub-pixels SP1, SP2, and SP3.

The sub-pixel SP1 includes a lower electrode LE1, an upper electrode UE1, and an organic layer OR1 each overlapping with the aperture AP1. The sub-pixel SP2 includes a lower electrode LE2, an upper electrode UE2, and an organic layer OR2 each overlapping with the aperture AP2. The sub-pixel SP3 includes a lower electrode LE3, an upper electrode UE3, and an organic layer OR3 each overlapping with the aperture AP3. In the example shown in FIG. 2, outer shapes of the upper electrode UE1 and the organic layer OR1 correspond to each other, outer shapes of the upper electrode UE2 and the organic layer OR2 correspond to each other, and outer shapes of the upper electrode UE3 and the organic layer OR3 correspond to each other.

The lower electrode LE1, the upper electrode UE1, and the organic layer OR1 constitute the display element 20 of the sub-pixel SP1. The lower electrode LE2, the upper electrode UE2, and the organic layer OR2 constitute the display element 20 of the sub-pixel SP2. The lower electrode LE3, the upper electrode UE3, and the organic layer OR3 constitute the display element 20 of the sub-pixel SP3.

The lower electrode LE1 is connected to the pixel circuit 1 which drives (the display element 20 of) the sub-pixel SP1 through a contact hole CH1. The lower electrode LE2 is connected to the pixel circuit 1 which drives (the display element 20 of) the sub-pixel SP2 through a contact hole CH2. The lower electrode LE3 is connected to the pixel circuit 1 which drives (the display element 20 of) the sub-pixel SP3 through a contact hole CH3.

In the example of FIG. 2, the contact holes CH1 and CH2 entirely overlap with the first partition 6x between the apertures AP1 and AP2 adjacent to each other in the direction Y. The contact hole CH3 entirely overlaps with the first partition 6x between two apertures AP3 adjacent in the direction Y. As an alternative example, at least parts of the contact holes CH1, CH2, and CH3 may not overlap with the first partition 6x.

In the example shown in FIG. 2, the lower electrodes LE1 and LE2 include protrusions PR1 and PR2, respectively. The protrusion PR1 protrudes from the body of the lower electrode LE1 (the portion overlapping with the aperture AP1) toward the contact hole CH1. The protrusion PR2 protrudes from the body of the lower electrode LE2 (the portion overlapping with the aperture AP2) toward the contact hole CH2. The contact holes CH1 and CH2 overlap with the protrusions PR1 and PR2, respectively.

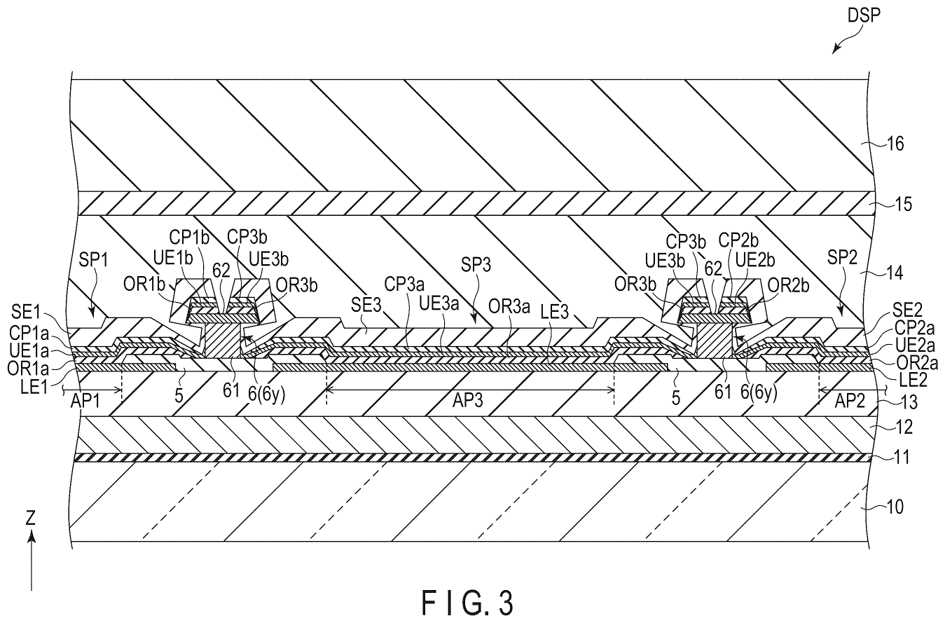

FIG. 3 is a schematic cross-sectional view showing the display device DSP along line III-III in FIG. 2. In the display device DSP, an insulating layer 11 referred to as an undercoat layer is arranged on the base 10 (i.e., on the surface of the side where the display element 20 and the like are arranged).

The insulating layer 11 has, for example, a three-layer stacked structure with a silicon oxide film (SiO), a silicon nitride film (SiN), and a silicon oxide film (SiO). The insulating layer 11 is not limited to the three-layer stacked structure, but may have a stacked structure with more than three layers, or may have a single-layer structure or a two-layer stacked structure.

A circuit layer 12 is arranged on the insulating layer 11. The circuit layer 12 includes various circuits and wires that drive the sub-pixels SP (SP1, SP2 and SP3) of the pixel circuit 1, the scanning line GL, the signal line SL, the power line PL, and the like shown in FIG. 1. The circuit layer 12 is covered with an insulating layer 13.

The insulating layer 13 functions as a planarization film which planarizes uneven parts generated by the circuit layer 12. Although not shown in FIG. 3, the above-described contact holes CH1, CH2, and CH3 are provided in the insulating layer 13.

The lower electrodes LE (LE1, LE2, and LE3) are arranged on the insulating layer 13. The rib 5 is arranged on the insulating layer 13 and the lower electrodes LE. Ends (parts) of the lower electrodes LE are covered with the rib 5.

The partition 6 includes a lower portion 61 arranged on the rib 5 and an upper portion 62 that covers an upper surface of the lower portion 61. The upper portion 62 has a greater width in direction X and direction Y than the lower portion 61. As a result, the partition 6 has a shape in which both ends of the upper portion 62 protrude beyond side surfaces of the lower portion 61. This shape of the partition 6 may also be referred to as an overhung shape.

The organic layers OR (OR1, OR2, and OR3) and the upper electrodes UE (UE1, UE2, and UE3) constitute the display element 20 together with the above-described lower electrodes LE (LE1, LE2, and LE3) but, as shown in FIG. 3, the organic layer OR1 includes a first organic layer OR1a and a second organic layer OR1b that are separated from each other. The upper electrode UE1 includes a first upper electrode UE1a and a second upper electrode UE1b that are separated from each other. The first organic layer OR1a is in contact with the lower electrode LE1 through the aperture AP1 and covers a part of the rib 5. The second organic layer OR1b is located on the upper portion 62. The first upper electrode UE1a is opposed to the lower electrode LE1 and covers the first organic layer OR1a. Furthermore, the first upper electrode UE1a is in contact with side surfaces of the lower portion 61. The second upper electrode UE1b is located above the partition 6 and covers the second organic layer OR1b.

In addition, as shown in FIG. 3, the organic layer OR2 includes a first organic layer OR2a and a second organic layer OR2b that are separated from each other. The upper electrode UE2 includes a first upper electrode UE2a and a second upper electrode UE2b that are separated from each other. The first organic layer OR2a is in contact with the lower electrode LE2 through the aperture AP2 and covers a part of the rib 5. The second organic layer OR2b is located on the upper portion 62. The first upper electrode UE2a is opposed to the lower electrode LE2 and covers the first organic layer OR2a. Furthermore, the first upper electrode UE2a is in contact with side surfaces of the lower portion 61. The second upper electrode UE2b is located above the partition 6 and covers the second organic layer OR2b.

In addition, as shown in FIG. 3, the organic layer OR3 includes a first organic layer OR3a and a second organic layer OR3b that are separated from each other. The upper electrode UE3 includes a first upper electrode UE3a and a second upper electrode UE3b that are separated from each other. The first organic layer OR3a is in contact with the lower electrode LE3 through the aperture AP3 and covers a part of the rib 5. The second organic layer OR3b is located on the upper portion 62. The first upper electrode UE3a is opposed to the lower electrode LE3 and covers the first organic layer OR3a. Furthermore, the first upper electrode UE3a is in contact with the side surfaces of the lower portion 61. The second upper electrode UE3b is located above the partition 6 and covers the second organic layer OR3b.

In the example shown in FIG. 3, the sub-pixels SP1, SP2 and SP3 include cap layers CP1, CP2 and CP3 for adjusting the optical property of the light emitted from light emitting layers of the respective organic layers OR1, OR2 and OR3.

The cap layer CP1 includes a first cap layer CP1a and a second cap layer CP1b that are separated from each other. The first cap layer CP1a is located in the aperture AP1 and is arranged on the first upper electrode UE1a. The second cap layer CP1b is located above the partition 6 and is arranged on the second upper electrode UE1b.

The cap layer CP2 includes a first cap layer CP2a and a second cap layer CP2b that are separated from each other. The first cap layer CP2a is located in the aperture AP2 and is arranged on the first upper electrode UE2a. The second cap layer CP2b is located above the partition 6 and is arranged on the second upper electrode UE2b.

The cap layer CP3 includes a first cap layer CP3a and a second cap layer CP3b that are separated from each other. The first cap layer CP3a is located in the aperture AP3 and is arranged on the first upper electrode UE3a. The second cap layer CP3b is located above the partition 6 and is arranged on the second upper electrode UE3b.

Sealing layers SE1, SE2 and SE3 are provided in the sub-pixels SP1, SP2 and SP3, respectively. The sealing layer SE1 continuously covers the members of the sub-pixel SP1 including the first cap layer CP1a, the partition 6, and the second cap layer CP1b. The sealing layer SE2 continuously covers the members of the sub-pixel SP2 including the first cap layer CP2a, the partition 6, and the second cap layer CP2b. The sealing layer SE3 continuously covers the members of the sub-pixel SP3 including the first cap layer CP3a, the partition 6, and the second cap layer CP3b.

In the example shown in FIG. 3, the second organic layer OR1b, the second upper electrode UE1b, the second cap layer CP1b, and the sealing layer SE1 on the partition 6 between the sub-pixels SP1 and SP3 are separated from the second organic layer OR3b, the second upper electrode UE3b, the second cap layer CP3b, and the sealing layer SE3 on the partition 6. In addition, the second organic layer OR2b, the second upper electrode UE2b, the second cap layer CP2b, and the sealing layer SE2 on the partition 6 between the sub-pixels SP2 and SP3 are separated from the second organic layer OR3b, the second upper electrode UE3b, the second cap layer CP3b, and the sealing layer SE3 on the partition 6.

The sealing layers SE1, SE2 and SE3 are covered with a resin layer 14. The resin layer 14 is covered with a sealing layer 15. Furthermore, the sealing layer 15 is covered with a resin layer 16.

The insulating layer 13 and the resin layers 14 and 16 are formed of organic materials. The rib 5, the sealing layer 15, and SE (SE1, SE2 and SE3) are formed of, for example, an inorganic material such as silicon nitride (SiNx).

The lower portion 61 of the partition 6 is conductive. The upper portion 62 of the partition 6 may also be conductive. The lower electrode LE may be formed of a transparent conductive oxide such as indium tin oxide (ITO) or may have a stacked structure of a metal material such as silver (Ag) and a conductive oxide. The upper electrode UE is formed of, for example, a metallic material such as an alloy (MgAg) of magnesium and silver. The upper electrode UE may be formed of a conductive oxide such as ITO.

When the potential of the lower electrode LE is relatively higher than the potential of the upper electrode UE, the lower electrode corresponds to an anode, and the upper electrode UE corresponds to a cathode. In addition, when the potential of the upper electrode UE is relatively higher than that of the lower electrode LE, the upper electrode UE corresponds to an anode, and the lower electrode LE corresponds to a cathode.

The organic layer OR includes a pair of functional layers, and a light emitting layer arranged between these functional layers. As an example, the organic layer OR has a structure in which a hole-injection layer, a hole-transport layer, an electron blocking layer, a light emitting layer, a hole blocking layer, an electron-transport layer, and an electron-injection layer are stacked in this order.

The cap layer CP (CP1, CP2, and CP3) is formed of, for example, a multilayer body of a plurality of transparent thin films. As the plurality of thin films, the multilayer body may include a thin film formed of an inorganic material and a thin film formed of an organic material. In addition, these thin films have refractive indices different from each other. The materials of the thin films constituting the multilayer body are different from the materials of the upper electrode UE and are also different from the materials of the sealing layer SE. The cap layer CP may be omitted.

A common voltage is supplied to the partition 6. This common voltage is supplied to each of the upper electrodes UE (first upper electrodes UE1a, UE2a, and UE3a) that are in contact with the side surfaces of the lower portion 61. A pixel voltage is supplied to the lower electrode LE (LE1, LE2, and LE3) through the pixel circuit 1 included in each sub-pixel SP (SP1, SP2, and SP3).

When a potential difference is formed between the lower electrode LE1 and the upper electrode UE1, the light emitting layer of the first organic layer OR1a emits light of the red wavelength range. When a potential difference is formed between the lower electrode LE2 and the upper electrode UE2, the light emitting layer of the first organic layer OR2a emits light of the green wavelength range. When a potential difference is formed between the lower electrode LE3 and the upper electrode UE3, the light emitting layer of the first organic layer OR3a emits light of the blue wavelength range.

As another example, the light emitting layers of the organic layers OR1, OR2, and OR3 may emit light of the same color (for example, white). In this case, the display device DSP may include a color filter that converts the light emitted from the light emitting layers into light of the color corresponding to the sub-pixels SP1, SP2, and SP3. In addition, the display device DSP may include a layer including quantum dots that are excited by the light emitted from the light emitting layers to generate the light of the colors corresponding to the sub-pixels SP1, SP2, and SP3.

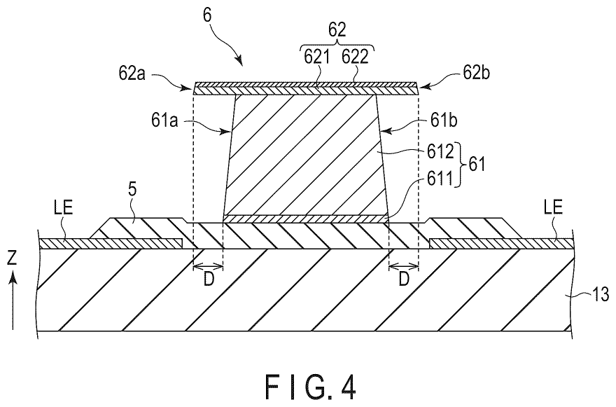

FIG. 4 is a schematic enlarged cross-sectional view of the partition 6. In FIG. 4, the elements other than the rib 5, the partition 6, the insulating layer 12 and a pair of lower electrodes LE are omitted. The pair of lower electrodes LE correspond to any of the above-described lower electrodes LE1, LE2 or LE3. In addition, the first partition 6x and the second partition 6y described above have the same structure as the partition 6 shown in FIG. 4.

In the example shown in FIG. 4, the lower portion 61 of the partition 6 includes a barrier layer 611 arranged on the rib 5, and a metal layer 612 arranged on the barrier layer 611. The barrier layer 611 is formed of a material different from the metal layer 612, for example, a metal material such as molybdenum. The metal layer 612 is formed to be thicker than the barrier layer 611. The metal layer 612 may have a single-layer structure or a multilayer structure of different metal materials. As an example, the metal layer 612 is formed of, for example, aluminum (Al) or an aluminum alloy.

The upper portion 62 is thinner than the lower portion 61. In the example shown in FIG. 4, the upper portion 62 includes a first layer 621 arranged on the metal layer 612, and a second layer 622 arranged on the first layer 621. As an example, the first layer 621 is formed of, for example, titanium (Ti) and the second layer 622 is formed of, for example, ITO. It has been described that the upper portion 62 has a two-layer stacked structure, but the upper portion 62 may have a single-layer structure formed of, for example, a metal material such as titanium. In addition, the upper portion 62 may also be formed of a material other than a metal material, and may be formed of an inorganic material such as silicon oxide (SiO). Furthermore, the upper portion 62 may be formed by stacking an appropriate combination of the conductive oxide such as ITO, the metal material such as titanium, and the inorganic material such as silicon oxide, which have been described above, or may be formed of a single layer of any of the above-described materials.

In the example shown in FIG. 4, the width of the lower portion 61 becomes smaller toward the upper portion 62. In other words, the side surfaces 61a and 61b of the lower portion 61 are inclined to the direction Z. The upper portion 62 includes an end portion 62a protruding from the side surface 61a and an end portion 62b protruding from the side surface 61b.

An amount D by which the end portions 62a and 62b protrude from the side surfaces 61a and 61b (hereinafter referred to as an amount of protrusion D of the partition 6) is, for example, 2.0 μm or less. The amount of protrusion D of the partition 6 in the embodiment corresponds to a length (distance) in the width direction (direction X or direction Y) orthogonal to the direction Z of the partition 6, between a lower end (barrier layer 611) of the sides 61a and 61b, and the end portions 62a and 62b. The amount of protrusion D of the partition 6 may be a length in the width direction orthogonal to the direction Z of the partition 6, between upper ends of the side surfaces 61a and 61b, and the end portions 62a and 62b.

The structure of the partition 6 and the materials of each part of the partition 6 may be selected as appropriate by considering, for example, a method of forming the partition 6, and the like.

In the embodiment, the partition 6 is formed to divide the sub-pixels SP in plan view. The above-described organic layer OR is formed by, for example, anisotropic or directional vacuum evaporation but, when the organic material for forming the organic layer OR is evaporated over the entire base 10 in a state in which the partition 6 is arranged, the organic layer OR is hardly formed on the side surfaces of the partition 6 since the partition 6 has the shape shown in FIG. 3 and FIG. 4. According to this, the organic layer OR (display element 20) which is divided for each sub-pixel SP by the partition 6 can be formed.

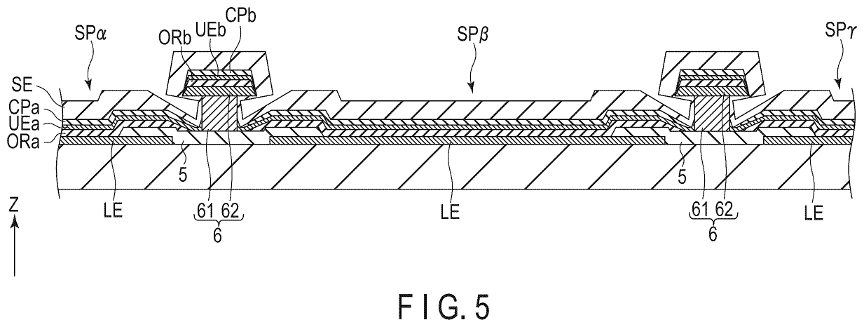

FIG. 5 to FIG. 7 are schematic cross-sectional views illustrating the display element 20 formed using the partition 6. Each of sub-pixels SPα, SPβ and SPγ shown in FIG. 5 to FIG. 7 corresponds to one of the sub-pixels SP1, SP2 and SP3.

In a state in which the partition 6 is arranged as described above, the organic layer OR, the upper electrode UE, the cap layer CP, and the sealing layer SE are formed in order on the entire base 10 by vapor deposition as shown in FIG. 5. The organic layer OR includes a light emitting layer which emits light of a color corresponding to the sub-pixel SPα. The organic layer OR is divided into a first organic layer ORa which covers the lower electrode LE and a second organic layer ORb on the partition 6, the upper electrode UE is divided into a first upper electrode UEa which covers the first organic layer ORa and a second upper electrode UEb which covers the second organic layer ORb, and the cap layer CP is divided into a first cap layer CPa which covers the first upper electrode UEa and a second cap layer CPb which covers the second upper electrode UEb, by the partition 6 in the overhung state. The first upper electrode UEa is in contact with the lower portion 61 of the partition 6. The sealing layer SE continuously covers the first cap layer CPa, the second cap layer CPb, and the partition 6.

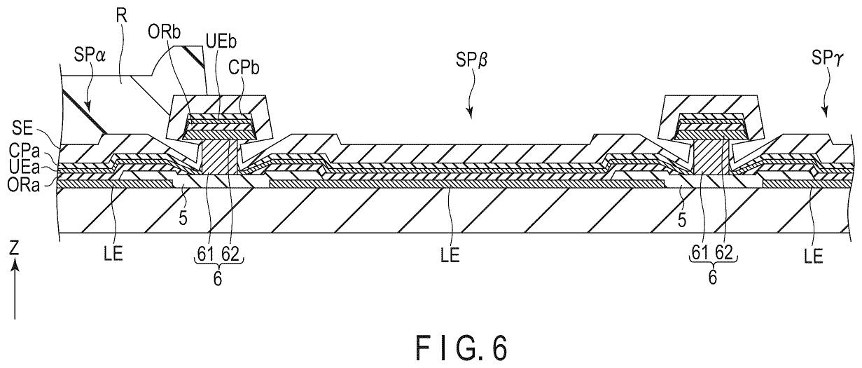

Next, a resist R is formed on the sealing layer SE as shown in FIG. 6. The resist R covers the sub-pixel SPα. In other words, the resist R is arranged directly above the first organic layer ORa, the first upper electrode UEa, and the first cap layer CPa, which are located in the sub-pixel SPα. The resist R is also located directly above portions close to the sub-pixel SPα, of the second organic layer ORb, the second upper electrode UEb, and the second cap layer CPb on the partition 6 between the sub-pixel SPα and the sub-pixel SPβ. In other words, at least a part of the partition 6 is exposed from the resist R.

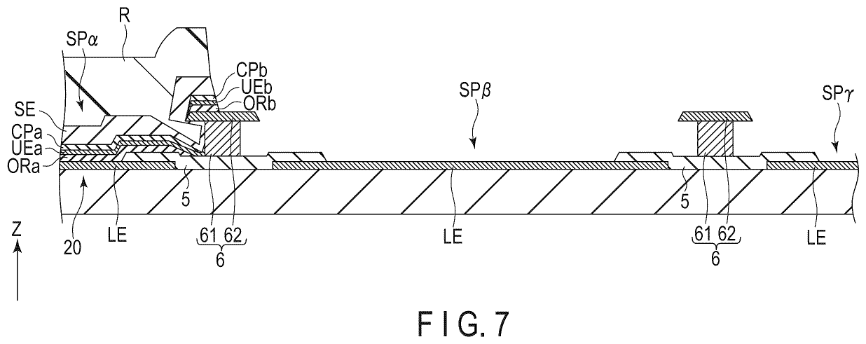

Furthermore, portions exposed from the resist R, of the organic layer OR, the upper electrode UE, the cap layer CP and the sealing layer SE, are removed as shown in FIG. 7, by etching using the resist R as a mask. The display element 20 including the lower electrode LE, the first organic layer ORa, the first upper electrode UEa, and the first cap layer CPa is thereby formed in the sub-pixel SPα. In contrast, the lower electrode LE is exposed in the sub-pixels SPβ and SPγ. The above-described etching includes, for example, dry etching of the sealing layer SE, wet etching and dry etching of the cap layer CP, wet etching of the upper electrode UE, and dry etching of the organic layer OR.

When the display element 20 of the sub-pixel SPα is formed as described above, the resist R is removed, and the display elements 20 of the sub-pixels SPβ and SPγ are formed in order similarly to the sub-pixel SPα.

The display elements 20 of the sub-pixels SP1, SP2, and SP3 are formed, and the resin layer 14, the sealing layer 15, and the resin layer 16 are formed, as exemplified for the above sub-pixels SPα, SPβ and SPγ, and the structure of the display device DSP shown in FIG. 3 is thereby implemented.

As described above, the partition 6 includes the lower portion 61 and the upper portion 62 protruding from the side surface of the lower portion 61 but, if the amount of protrusion D (eave width) of the partition 6 is not appropriate, the reliability of the display device DSP may be reduced.

More specifically, the display device DSP is configured such that the organic layer OR is divided for each sub-pixel SP by the partition 6 and, if the amount of protrusion D of the partition 6 is not sufficiently larger than the designed value, the organic layer OR may not be able to be appropriately divided. In addition, if the side surface of the lower portion 61 of the partition 6 is covered with the organic layer OR, the electric connection between the lower portion 61 and the upper electrode UE is inhibited. In contrast, the upper electrode UE is in contact with the side surface of the lower portion 61 of the partition 6, in the display device DSP but, if the amount of protrusion D of the partition 6 exceeds the designed value, the upper electrode UE may not be in contact with the side surface of the lower portion 61.

In other words, since a highly reliable display device DSP cannot be manufactured in a case where the above-described amount of protrusion D of the partition 6 is not appropriate, it is useful to measure the amount of protrusion D (i.e., the length between the side surface of the lower portion 61 of the partition 6 and the end portion of the upper portion 62) in the process of manufacturing the display device DSP.

Incidentally, in general, a plurality of display panels are formed on a motherboard including a plurality of bases 10, and each of the display panels cut from the motherboard is used to manufacture the display device DSP, in the process of manufacturing the display device DSP.

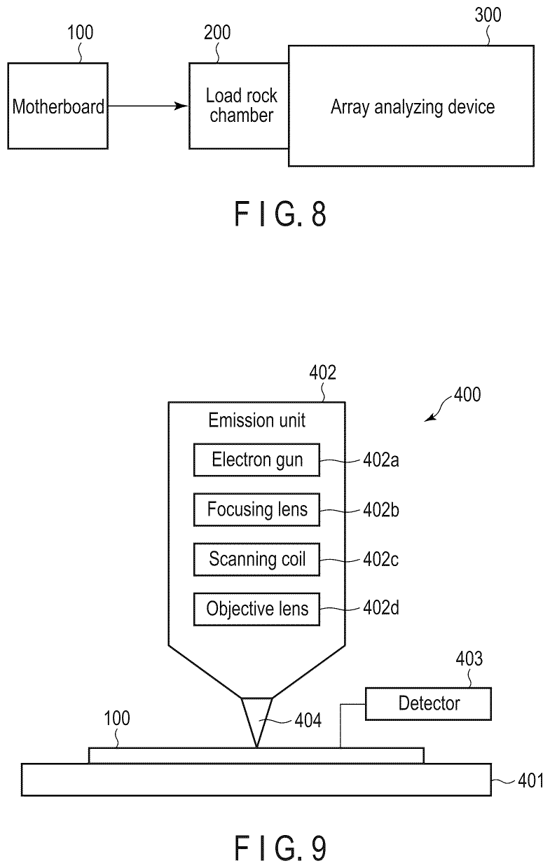

In the above-described process of manufacturing the display device DSP, a motherboard (array substrate) 100 is inserted into a motherboard inspection device 300 in which a vacuum state is maintained through a load lock chamber 200, and the quality of the motherboard 100 is inspected in the motherboard inspection device 300, as shown in FIG. 8.

In this case, for example, a scanning electron microscopy (SEM) is mounted on the motherboard inspection system 300 and, according to the motherboard inspection system 300, component (element) analysis for the motherboard 100 can be executed by an energy dispersive X-ray spectroscopy (EDX) attached to the SEM.

Therefore, if the SEM mounted on the above-described mother board inspection system 300 can be used, it is considered that the amount of protrusion D of the partition 6 can be measured (inspected) on a continuous flow basis.

A configuration of the above-described SEM will be simply described with reference to FIG. 9. As shown in FIG. 9, a SEM 400 includes a sample stand 401, an emission unit (irradiator) 402, and a detector 403. In addition, the emission unit 402 includes an electron gun 402a, focusing lens 402b, a scanning coil 402c, and an objective lens 402d.

The electron gun 402a generates an electron beam. The focusing lens 402b and the objective lens 402d focus the electron beam to an electron spot on a sample (in this case, the motherboard 100) placed on the sample stand 401. The emission unit 402 can thereby emit an electron beam 404 containing primary electrons to a sample. The scanning coil 402c scans (moves) an electron spot (i.e., the point of irradiation of the electron beam 404) where the electron beam is focused, on the sample. According to this, secondary electrons are generated from each of the points of irradiation of the electron beam 404, and the generated secondary electrons are detected by the detector 403. The SEM 400 can generate an image of the sample (hereinafter referred to as a SEM image), based on the secondary electrons (i.e., detection data) thus detected by the detector 403. Since the amount of generation of the secondary electrons varies with the irregularity structure on the surface of the sample, the SEM image can be an image which includes a surface shape of the sample. It is known that a SEM image has higher resolution than images captured by, for example, an optical microscope.

Measuring the amount of protrusion D of the partition 6 using SEM 400 as described above is assumed. In this case, for example, if it is assumed that the electron beam is emitted to the partition 6 from the direction Z (i.e., the direction perpendicular to the base 10), a SEM image including the surface shape of the upper surface of the upper portion 62 (i.e., the surface on the direction Z side) is generated and the amount of protrusion D of the partition 6 cannot be measured from the SEM image since the upper portion 62 of the partition 6 has a larger width than the lower portion 61 (i.e., the shape of the partition 6 is overhung). In other words, for example, if the electron beam is emitted to the partition 6 from the direction Z, the length of the upper portion 62 of the partition 6 in the direction X or the direction Y can only be measured.

In addition, even if an electron beam 404 is emitted from a side of a surface (i.e., a back surface) opposite to the surface of the side where the display element 20 and the like of the base 10 (motherboard 100) are arranged, only an SEM image including the surface shape of the back surface of the base 10 is generated, and the amount of protrusion D of the partition 6 cannot be measured.

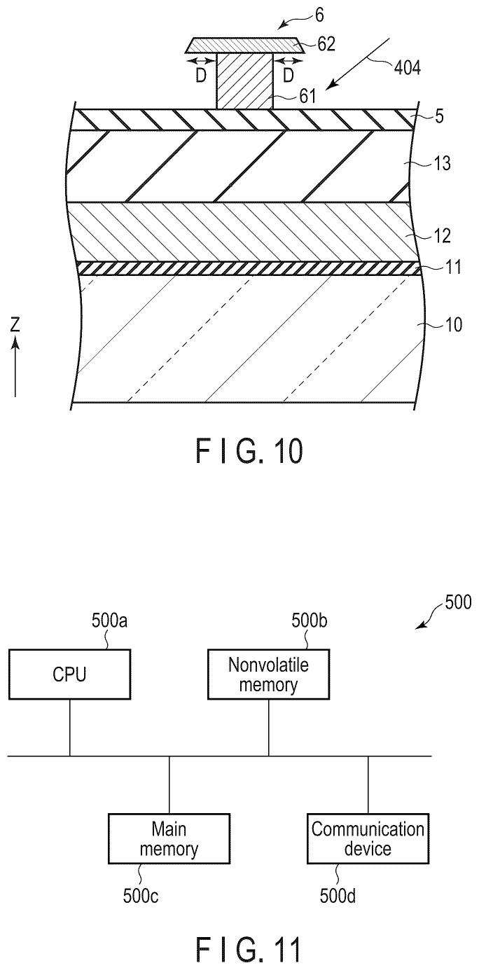

Therefore, in the embodiment, as shown in FIG. 10, the amount of protrusion D of the partition 6 is assumed to be measured using the SEM image generated by detecting secondary electrons generated by emitting the electron beam 404 from a direction (i.e., oblique direction or second direction) inclined to the vertical direction (direction Z or first direction) of the base 10 to the partition 6 (the area including at least a part of the side surface of the lower portion 61 and the area including at least a part of the end portion of the upper portion 62) formed on the base 10.

In the embodiment, the amount of protrusion D of the partition 6 is assumed to be measured by a measuring device which is communicably connected to the SEM 400 mounted on the above-described motherboard inspection system 300. The measuring device may be realized as a part of the motherboard inspection device 300 or realized as a device different from the motherboard inspection device 300. Alternatively, the measuring device may also be realized integrally with the above-described SEM 400.

The measuring device of the embodiment will be described below. FIG. 11 is a view showing an example of a hardware configuration of the measuring device.

A measuring device 500 shown in FIG. 11 is realized by, for example, a personal computer and includes a CPU 500a, a nonvolatile memory 500b, a main memory 500c, a communication device 500d, and the like.

The CPU 500a is a processor for controlling the operation of the measuring device 500 and executes various programs that are loaded from the nonvolatile memory 500b into the main memory 500c. The communication device 500d executes communication with external devices (for example, SEM 400, and the like) of the measuring device 500.

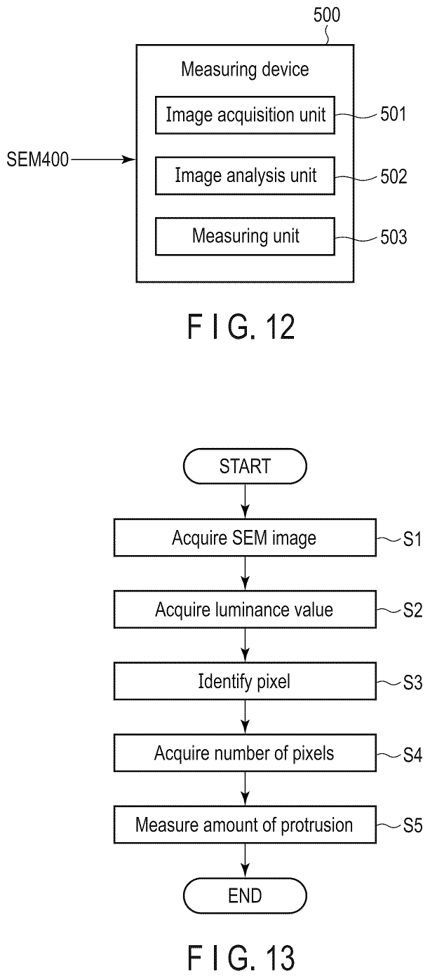

FIG. 12 is a view showing an example of a functional configuration of the measuring device 500. As shown in FIG. 12, the measuring device 500 includes an image acquisition unit 501, an image analysis unit 502, and a measuring unit 503.

Some or all of the units 501 to 503 included in the measuring device 500 are functional units realized by the above-described CPU 500a (i.e., the computer of the measuring device 500) executing predetermined programs (i.e., software), but may be realized by hardware such as an integrated circuit (IC) and the like or by a combination of software and hardware.

In the embodiment, the measuring device 500 is communicably connected to the SEM 400, and the image acquisition unit 501 acquires SEM images generated by the SEM 400 from the SEM 400 as described above. The image analysis unit 502 analyzes the SEM images acquired by the image acquisition unit 501. The measuring unit 503 measures the amount of protrusion D of the partition 6 formed on the above-described motherboard 100 (i.e., a length from the side surface of the lower portion 61 of the partition 6 to the end portion of the upper portion 62), based on the analysis results of the image analyzing unit 502.

An example of the processing procedure of the measuring device 500 of the embodiment will be described below with reference to a flowchart of FIG. 13.

First, when the motherboard 100 in which the insulating layer 11, the circuit layer 12, the insulating layer 13, the lower electrode LE, the rib 5, and the partition 6 are formed on the motherboard including a plurality of bases 10 is manufactured, the motherboard 100 is inserted into the motherboard inspection device 300 through the load lock chamber 200 shown in FIG. 8. In the motherboard inspection device 300, the SEM 400 generates SEM images and outputs the SEM images to the measurement system 500.

Incidentally, an electron beam is generally emitted from a direction perpendicular to the sample but, in the embodiment, the SEM 400 includes a Tilt function that enables the electron beam 404 to be emitted from an oblique direction to the motherboard 100 (base 10) as described above. The Tilt function is realized by mounting, for example, a deflection coil in the emission unit 402 provided in the SEM 400, and generating a magnetic field (magnetic field) with the deflection coil to change the direction of the electron beam 404 emitted (incident) on the motherboard 100 (i.e., to deflect the electron beam). The Tilt function is only required to realize making incidence of the electron beam 404 on the motherboard 100 (the partition 6 formed on the mother substrate 100) from an oblique direction. More specifically, the Tilt function may be realized by, for example, inclining the direction of the emission unit 402 provided in the SEM 400 or by, for example, inclining (the motherboard 100 mounted on) the sample stand 401.

In the embodiment, the SEM 400 using the above-described Tilt function outputs to the measuring device 500 the SEM image generated by detecting the secondary electrons generated by emitting the electron beam including the primary electrons to the area including at least a part of the side surface of the lower portion 61 of the partition 6 and at least a part of the end portion of the upper portion 62 from the oblique direction inclined from the direction (i.e., the direction Z) perpendicular to the motherboard 100 (base 10) (i.e., the SEM image generated by emitting the electron beam to the partition 6). In other words, the SEM image output from the SEM 400 to the measuring device 500 in the embodiment is considered as an image including the partition 6 (lower portion 61 and upper portion 62) obtained by observing the motherboard 100 from an oblique direction.

In the embodiment, the SEM image (image file) is assumed to be in, for example, a file format such as jpeg, but may be a file in any other format.

The SEM image output from the SEM 400 as described above is acquired by the image acquisition unit 501 in the measuring device 500 (step S1).

The SEM image acquired in step S1 is composed of a plurality of pixels, and each of the pixels holds a luminance value (pixel value) for displaying the SEM image. Therefore, the image analysis unit 502 acquires from the SEM image acquired in step S1 the luminance value held by each of the plurality of pixels constituting the SEM image (hereinafter simply referred to as a pixel luminance value) (step S2).

In the SEM image generated by emitting the electron beam 404 from the upper side of the partition 6 (i.e., emitting the electron beam 404 onto the surface of the base 10 on which the partition 6 is formed) as shown in FIG. 10 described above, a shadow generated by the upper portion 62 is included.

In this case, the image analysis unit 502 identifies a pixel (hereinafter referred to as a first pixel) corresponding to the lower end of the side surface of the lower portion 61 included in the SEM image (i.e., the end portion of the substrate 10 side), and a pixel (hereinafter referred to as a second pixel) corresponding to the end portion of the shadow (hereinafter simply referred to as a shadow of the upper portion 62) generated by the upper portion 62, based on the luminance values of the plurality of pixels constituting the SEM image acquired in step S2 (step S3). The process of step S3 corresponds to the process of identifying coordinate values of the lower end of the side surface of the lower portion 61 and coordinates of the end portion of the shadow of the upper portion 62, on the SEM image.

When the process of step S3 is executed, the image analysis unit 502 refers to the SEM image acquired in step S1 to acquire (count) the number of pixels arranged between the first and second pixels identified in step S3 (step S4).

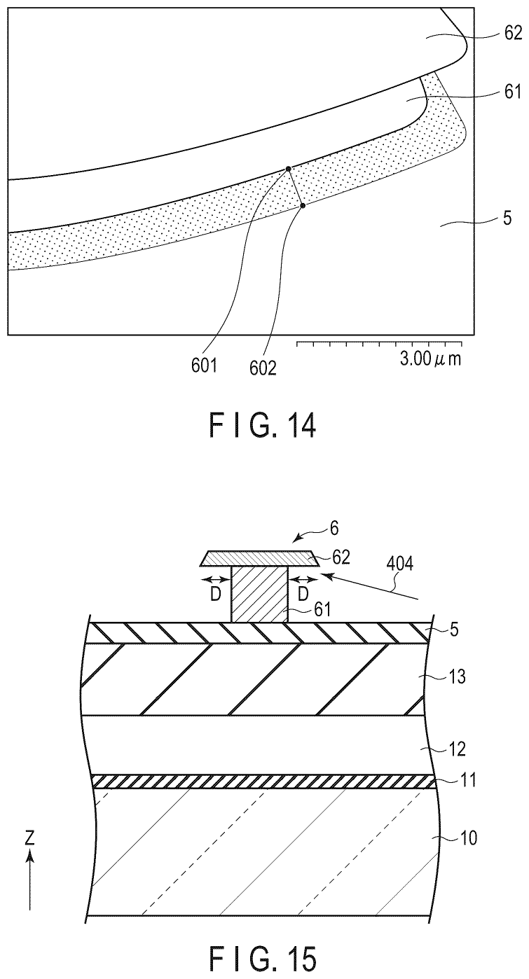

The above-described processes of steps S3 and S4 will be specifically described below with reference to FIG. 14. FIG. 14 shows an example of the SEM image acquired in step S1 (i.e., the SEM image generated by the SEM 400). As shown in FIG. 14, a portion of the side surface of the lower portion 61 and a portion of the end portion of the upper portion 62, of the partition 6 formed on the rib 5, are included in the SEM image.

In step S3, the image analysis unit 502 detects the lower end of the side surface of the lower portion 61 of the partition 6, based on the luminance value of each of the plurality of pixels constituting the SEM image. The lower end of the side surface of the lower portion 61 of the partition 6 is detected by obtaining the boundary (edge) between the side surface of the lower portion 61 and the rib 5, based on the amount of change in the luminance values of pixels that are close to the luminance value of each of the plurality of pixels constituting the SEM image. The image analysis unit 502 identifies as the first pixel, for example, one pixel 601 of the plurality of pixels located at the detected lower end of the side surface of the lower portion 61. In this case, the image analysis unit 502 may identify as the first pixel a pixel at a predetermined position among the plurality of pixels located at the lower end of the side surface of the above-described lower portion 61 (for example, a pixel located in the center at the lower end of the side surface of the lower portion 61 included in the SEM image, or the like).

In addition, the image analysis unit 502 detects the end portion of the shadow of the upper portion 62, based on the luminance value of each of the plurality of pixels constituting the SEM image. The shadow of the upper portion 62 is the area indicated by dots in FIG. 14. In addition, the end portion of the shadow of the upper portion 62 is detected by obtaining the boundary (edge) between the shadow of the upper portion 62 and the rib 5, based on the amount of change in the luminance values of pixels that are close to the luminance value of each of the plurality of pixels constituting the SEM image. The image analysis unit 502 identifies as the second pixel one pixel 602 that is the closest to, for example, pixel 601 (first pixel) of the plurality of pixels located at the end portion of the detected shadow of the upper portion 62 (for example, a pixel located in the direction perpendicular to the side surface of the lower portion 61 corresponding to the pixel 601). In this case, the image analysis unit 502 may identify as the second pixel a pixel at a predetermined position among the plurality of pixels located at the end portion of the shadow of the upper portion 62 (for example, a pixel located in the center at the end portion of the shadow of the upper portion 62 included in the SEM image, or the like).

In step S4, the image analysis unit 502 acquires the number of pixels arranged between the pixel 601 and the pixel 602.

As shown in FIG. 14, the end portion of the shadow of the upper portion 62 (i.e., the shadow generated on the rib 5) is often blurred as compared to, for example, the lower end of the side surface of the lower portion 61. Therefore, a different second pixel is considered to be identified from the SEM image, depending on the definition of the end portion of the shadow of the above-described upper portion 62, but the definition of the boundary may be selected (determined) as appropriate depending on the environment in which the SEM image is generated (i.e., the electron beam is emitted) or the like.

In addition, it has been described that the number of pixels arranged between one set of first and second pixels (pixels 601 and 602) is obtained, but the number of pixels may be an average value of the number of pixels arranged between a plurality of sets of first and second pixels, or the like.

Next, the measuring unit 503 measures the amount of protrusion D of the partition 6, based on the number of pixels acquired in step S4 (step S5).

In step S5, the measuring unit 503 executes a process of converting the number of pixels acquired in step S4 into the length of the shadow of the upper portion 62, based on, for example, conversion information prepared in advance. The length of the shadow of the upper portion 62 in this case is the length from the lower end of the side surface of the lower portion 61 corresponding to the above-described first pixel to the end portion of the shadow of the upper portion 62 corresponding to the second pixel (i.e., the length of the shadow in the direction of separating from the side surface of the lower portion 61).

The conversion information is generated based on, for example, an SEM image including a sample of known size (length) (i.e., a reference SEM image generated by emitting the electron beam to the sample). More specifically, the conversion information indicating the length corresponding to one pixel is generated by counting the number of pixels arranged between (a pixel corresponding to) one end and (a pixel corresponding to) the other end of the sample included in the reference SEM image and dividing the known size of the sample by the number of pixels. According to such conversion information, the number of pixels can be converted into the length of the shadow of the upper portion 62 by multiplying the length corresponding to one pixel indicated by the conversion information by the number of pixels acquired in step S4. The conversion information may be any information that enables the number of pixels to be converted into the length (i.e., information that the correspondence between the number of pixels and the length is defined).

As described above, the length of the shadow of the upper portion 62 converted from the number of pixels acquired in step S4 is different from the amount of protrusion D of the partition 6, but varies according to the amount of protrusion D of the partition 6. For this reason, the measuring unit 503 measures the amount of protrusion D of the partition 6 from the length of the shadow of the upper portion 62 converted from the number of pixels.

More specifically, the amount of protrusion D of the partition 6 can be calculated by applying, for example, the length of the shadow of the upper portion 62 converted from the number of pixels acquired in step S4 to a function that a relationship between the length of the shadow of the upper portion 62, which is an actual measurement value, and the amount of protrusion D of the partition 6 including the upper portion 62 is defined, or the like.

In addition, the amount of protrusion D of the partition 6 may be measured (calculated) using a machine learning model generated by a machine learning algorithm such as a neural network. Such a machine learning model may be configured to output the amount of protrusion D of the partition 6 by inputting the number of pixels corresponding to the length of the shadow of the upper portion 62 (i.e., to predict the amount of protrusion D of the partition 6 from the number of pixels corresponding to the length of the shadow of the upper portion 62), by learning a data set including both the number of pixels corresponding to the length of the shadow of the upper portion 62 acquired manually or automatically from the SEM image including the partition 6 in which the amount of protrusion D is already known (i.e., the number of pixels arranged between the first and second pixels identified from the SEM image) and the known amount of protrusion D of the partition 6.

When the amount of protrusion D of the partition 6 measured by executing the above-described process shown in FIG. 13 is appropriate, the display element 20 of each sub-pixel SP can be formed in the motherboard 100 as described above with reference to FIG. 5 to FIG. 7.

Measuring the amount of protrusion D of a part of the partition 6 formed on the motherboard 100 has been described with reference to FIG. 13, but the process shown in FIG. 13 may be executed a plurality of times to measure the amount of protrusion D at a plurality of parts of the partition 6.

As described above, in the embodiment, the partition 6 having both the lower portion 61 arranged on the base 10 (mother base) and the upper portion 62 protruding from the side surface of the lower portion 61 is formed, the SEM image (first image) generated by detecting the secondary electrons generated by emitting the electron beam including the primary electrons to the area including at least a part of the side surface of the lower portion 61 and at least a part of the end portion of the upper portion 62 from the direction (second direction) inclined from a direction (first direction) perpendicular to the base 10 is acquired, the acquired SEM image is analyzed, and the amount of protrusion D (i.e., the length from the side surface of the lower portion 61 to the end portion of the upper portion 62) of the partition 6 is measured based on the analysis result.

In the embodiment, since the display device DSP can be manufactured by measuring the amount of protrusion D of the partition 6 (i.e., confirming whether or not the amount of protrusion D of the partition 6 is appropriate), by the above-described configuration, decrease in the reliability of the display device DSP can be suppressed.

In addition, in the embodiment, since the amount of protrusion D of the partition 6 is measured using the SEM 400 mounted on the motherboard inspection device 300 used to inspect the quality of the motherboard 100, it is possible to achieve continuous flow measurement using existing installations can be realized.

Furthermore, in this embodiment, the first pixel corresponding to the lower end (i.e., the end portion on the base 10 side) of the side surface of the lower portion 61 and the second pixel corresponding to the end portion of the shadow of the upper portion 62 are identified based on the luminance values of the plurality of pixels constituting the SEM image, and the amount of protrusion D of the partition 6 is measured based on the number of pixels arranged between the identified first and second pixels. In the embodiment, with this configuration, the amount of protrusion D of the partition 6 can be measured using the shadow of the upper portion 62 included in the SEM image generated by emitting the electron beam 404 toward the surface on the side opposite to the base 10 of the upper portion 62.

In the embodiment, as described above, the amount of protrusion D of the partition 6 may be measured based on the number of pixels arranged between the first and second pixels identified from the SEM image, but the amount of protrusion D of the partition 6 can be measured using, for example, the conversion information or the machine learning model. In this case, the conversion information may be prepared in advance based on, for example, a reference SEM image (second image) generated by emitting the electron beam 404 toward a sample whose size (length) is already known. In addition, the machine learning model may be prepared in advance by learning a data set including both the number of pixels arranged between the first and second pixels identified from the SEM image (third image) generated by emitting the electron beam 404 to the partition 6 (sample) whose amount of protrusion D is already known and the known amount of protrusion D.

In addition, in the embodiment, it has been described that the amount of protrusion D of the partition 6 is measured based on the number of pixels arranged between the first and second pixels identified based on the luminance values of the plurality of pixels constituting the SEM image, but predetermined image processing may be executed to identify (extract) the first and second pixels that are useful for measurement of the amount of protrusion D of the partition 6 or a machine learning model constructed to extract the useful first and second images from the SEM image may be used.

Furthermore, in the embodiment, it has been described that the amount of protrusion D of the partition 6 is measured by executing the process shown in FIG. 13 but, for example, a machine learning model learning a data set including both the SEM image generated by emitting the electron beam 404 to the partition 6 (sample) whose amount of protrusion D is already known and the known amount of protrusion D of the partition 6 may be prepared. According to such a configuration, for example, the measuring device 500 can acquire the amount of protrusion D of the partition 6 output from the machine learning model (i.e., predict the amount of protrusion D of the partition 6 included in the SEM image from the SEM image) by inputting the SEM image output from the SEM 400 to the machine learning model.

Incidentally, in the embodiment, it has been described that the SEM 400 includes the Tilt function and that the electron beam 404 is emitted to the surface of the side opposite to the base 10 of the upper portion 62 as shown in FIG. 10 but, for example, if the electron beam 404 is emitted to the surface (surface under eave) on the base 10 side of the upper portion 62 as shown in FIG. 15 by improving the Tilt function, the SEM image including the length (i.e., the amount of protrusion D of the partition 6) from the upper end of the side surface of the lower portion 61 (i.e., the end portion on the side opposite to the base 10) to the end portion of the upper portion 62 is generated, and the amount of protrusion D of the partition 6 can be thereby measured with high accuracy. In this case, the first pixel corresponding to the upper end of the side surface of the lower portion 61 and the second pixel corresponding to the end portion of the upper portion 62 may be identified, and the amount of protrusion D of the partition 6 may be measured based on the number of pixels arranged between the first and second pixels.

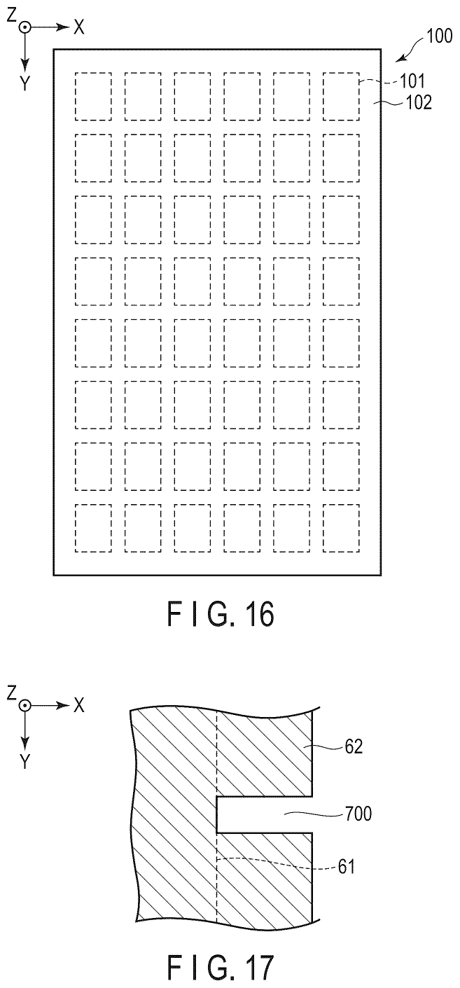

Furthermore, as shown in FIG. 16, the motherboard 100 (mother base) includes a plurality of panel areas 101 and a peripheral area 102. The plurality of panel areas 101 are areas where display panels are formed and are arrayed in a matrix in the direction X and the direction Y. The peripheral area 102 is an area which exists around the plurality of panel areas 101 to divide the plurality of panel areas 101.

If the above-described partition 6 is assumed to be formed for both the panel area 101 and the peripheral area 102 of the motherboard 100, the partition 6 arranged in the plurality of panel areas 101 is a component necessary for forming each of the sub-pixels SP in the process in which the display panel used for manufacturing the display device DSP is formed. In contrast, the partition 6 arranged in the peripheral area 102 does not contribute to the quality of the display device DSP (display panel).

For this reason, as shown in FIG. 17, for example, a part of the upper portion 62 of the partition 6 arranged in the peripheral area 102 (i.e., the portion protruding from the lower portion 61) may be cut (removed) by a focused ion beam (FIB) emitted from a direction (direction Z) perpendicular to the base 10 (motherboard 100), and the electron beam 404 may be emitted from a vertical direction to the area including the partition 6 (i.e., a cut portion 700 of the upper portion 62) from which a part of the upper portion 62 is cut to generate the SEM image. According to such a configuration, for example, it is possible to identify the first and second pixels corresponding to both ends of the cut portion 700 in the direction X shown in FIG. 17, from the SEM image, and to measure the amount of protrusion D of the partition 6 based on the number of pixels arranged between the first and second pixels.

All measuring methods and measuring devices, which are implementable with arbitrary changes in design by a person of ordinary skill in the art based on the measuring methods and measuring devices described above as the embodiments of the present invention, belong to the scope of the present invention as long as they encompass the spirit of the present invention.

Various modifications are easily conceivable within the category of the idea of the present invention by a person of ordinary skill in the art, and these modifications are also considered to belong to the scope of the present invention. For example, additions, deletions or changes in design of the constituent elements or additions, omissions or changes in condition of the processes may be arbitrarily made to the above embodiments by a person of ordinary skill in the art, and these modifications also fall within the scope of the present invention as long as they encompass the spirit of the present invention.

In addition, the other advantages of the aspects described in the above embodiments, which are obvious from the descriptions of the specification or which are arbitrarily conceivable by a person of ordinary skill in the art, are considered to be achievable by the present invention as a matter of course.

What is claimed is:

1. A measuring method comprising:
forming a partition including a lower portion arranged on a base and an upper portion protruding from a side surface of the lower portion;
acquiring a first image generated by detecting a secondary electron generated by emitting an electron beam including a primary electron to an area including at least a part of the side surface of the lower portion and at least a part of an end portion of the upper portion from a second direction inclined from a first direction perpendicular to the base;
analyzing the acquired first image; and
measuring an amount of protrusion by which the end portion of the upper portion protrudes from the side surface of the lower portion, based on the analysis result.

2. The measuring method of claim 1, wherein
the electron beam is emitted toward a surface on a side opposite to the base of the upper portion,
the analyzing includes identifying a first pixel corresponding to an end portion on the base side of the side surface of the lower portion, and a second pixel corresponding to an end portion of a shadow generated by the upper portion, based on luminance values of a plurality of pixels constituting the first image, and
the measuring includes measuring the amount of protrusion based on the number of pixels arranged between the identified first and second pixels.

3. The measuring method of claim 2, wherein
the measuring includes converting the number of pixels into a length of a shadow generated by the upper portion, based on conversion information indicating a length corresponding to one pixel, and measuring the amount of protrusion based on the length of the shadow converted from the number of pixels, and
the conversion information is prepared in advance based on a second image generated by detecting a secondary electron generated by emitting an electron beam including a primary electron to a sample whose size is already known.

4. The measuring method of claim 2, wherein
the measuring includes acquiring the amount of protrusion output from a machine learning model by inputting the number of pixels arranged between the identified first and second pixels to the machine learning model, the machine learning model being generated by learning a data set prepared in advance, and
the data set includes the number of pixels arranged between the first and second pixels identified from a third image generated by detecting a secondary electron generated by emitting the electron beam including the primary electron to the area including at least a part of the side surface of the lower portion included in the partition from which the amount of protrusion is already known and at least a part of the end portion of the upper portion included in the partition, and the already known amount of protrusion.

5. The measuring method of claim 1, wherein
the electron beam is emitted toward a surface on the base side of the upper portion,
the analyzing includes identifying a first pixel corresponding to an end portion on a side opposite to the base side of the side surface of the lower portion, and a second pixel corresponding to an end portion of the upper portion, based on luminance values of a plurality of pixels constituting the first image, and
the measuring includes measuring the amount of protrusion based on the number of pixels arranged between the identified first and second pixels.

6. A measuring method comprising:
forming an insulating layer arranged on a base;
forming a lower electrode arranged on the insulating layer;
forming a rib which covers a part of the lower electrode and which includes an aperture overlapping with the lower electrode;
forming a partition including a lower portion arranged on the rib and an upper portion protruding from a side surface of the lower portion;
acquiring a first image generated by detecting a secondary electron generated by emitting an electron beam including a primary electron to an area including at least a part of the side surface of the lower portion and at least a part of an end portion of the upper portion from a second direction inclined from a first direction perpendicular to the base;
analyzing the acquired first image; and
measuring an amount of protrusion by which the end portion of the upper portion protrudes from the side surface of the lower portion, based on the analysis result.

7. The measuring method of claim 6, wherein
the lower portion is formed of a first metal material, and
the upper portion is formed of a second metal material different from the first metal material.

8. The measuring method of claim 7, wherein
the first metal material includes aluminum or an aluminum alloy, and
the second metal material includes titanium.

9. The measuring method of claim 6, wherein
the electron beam is emitted toward a surface on a side opposite to the base of the upper portion,
the analyzing includes identifying a first pixel corresponding to an end portion on the base side of the side surface of the lower portion, and a second pixel corresponding to an end portion of a shadow generated by the upper portion, based on luminance values of a plurality of pixels constituting the first image, and
the measuring includes measuring the amount of protrusion based on the number of pixels arranged between the identified first and second pixels.

10. The measuring method of claim 9, wherein
the measuring includes converting the number of pixels into a length of a shadow generated by the upper portion, based on conversion information indicating a length corresponding to one pixel, and measuring the amount of protrusion based on the length of the shadow converted from the number of pixels, and
the conversion information is prepared in advance based on a second image generated by detecting a secondary electron generated by emitting an electron beam including a primary electron to a sample whose size is already known.

11. The measuring method of claim 9, wherein
the measuring includes acquiring the amount of protrusion output from a machine learning model by inputting the number of pixels arranged between the identified first and second pixels to the machine learning model, the machine learning model being generated by learning a data set prepared in advance, and
the data set includes the number of pixels arranged between the first and second pixels identified from a third image generated by detecting a secondary electron generated by emitting the electron beam including the primary electron to the area including at least a part of the side surface of the lower portion included in the partition from which the amount of protrusion is already known and at least a part of the end portion of the upper portion included in the partition, and the already known amount of protrusion.

12. The measuring method of claim 6, wherein
the electron beam is emitted toward a surface on the base side of the upper portion,
the analyzing includes identifying a first pixel corresponding to an end portion on a side opposite to the base side of the side surface of the lower portion, and a second pixel corresponding to an end portion of the upper portion, based on luminance values of a plurality of pixels constituting the first image, and
the measuring includes measuring the amount of protrusion based on the number of pixels arranged between the identified first and second pixels.

13. The measuring method of claim 6, further comprising:
forming an organic layer which is in contact with the lower electrode through the aperture after measuring the amount of protrusion; and
forming an upper electrode arranged on the organic layer.

14. The measuring method of claim 13, further comprising:
forming a cap layer arranged on the upper electrode; and
forming a sealing layer arranged on the cap layer.

15. The measuring method of claim 6, wherein
the insulating layer is formed of an organic material, and
the rib is formed of an inorganic material.

16. A measuring device comprising:
an emission unit configured to emit an electron beam including a primary electron to an area including at least a part of side surface of a lower portion and at least a part of an end portion of an upper portion protruding from the side surface of the lower portion from a second direction inclined from a first direction perpendicular to a base where a partition including the lower portion and the upper portion;
a detector configured to detect a secondary electron generated by the emission of the electron beam;
an acquisition unit configured to acquire a first image generated by detection data from the detector;
an analysis unit configured to analyze the acquired first image; and
a measuring unit configured to measure an amount of protrusion by which the end portion of the upper portion protrudes from the side surface of the lower portion, based on the analysis result.

17. The measuring device of claim 16, wherein
the electron beam is emitted toward a surface on a side opposite to the base of the upper portion,
the analysis unit is configured to identify a first pixel corresponding to an end portion on the base side of the side surface of the lower portion, and a second pixel corresponding to an end portion of a shadow generated by the upper portion, based on luminance values of a plurality of pixels constituting the first image, and
the measuring unit is configured to measure the amount of protrusion, based on the number of pixels arranged between the identified first and second pixels.

18. The measuring device of claim 17, wherein
the measuring unit is configured to convert the number of pixels into a length of a shadow generated by the upper portion, based on conversion information indicating a length corresponding to one pixel, and measure the amount of protrusion, based on the length of the shadow converted from the number of pixels, and
the conversion information is prepared in advance based on a second image generated by detecting a secondary electron generated by emitting an electron beam including a primary electron to a sample whose size is already known.

19. The measuring device of claim 17, wherein
the measuring unit is configured to acquire the amount of protrusion output from a machine learning model by inputting the number of pixels arranged between the identified first and second pixels to the machine learning model, the machine learning model being generated by learning a data set prepared in advance, and
the data set includes the number of pixels arranged between the first and second pixels identified from a third image generated by detecting a secondary electron generated by emitting the electron beam including the primary electron to the area including at least a part of the side surface of the lower portion included in the partition from which the amount of protrusion is already known and at least a part of the end portion of the upper portion included in the partition, and the already known amount of protrusion.

20. The measuring device of claim 16, wherein
the electron beam is emitted toward a surface on the base side of the upper portion,
the analysis unit is configured to identify a first pixel corresponding to an end portion on a side opposite to the base side of the side surface of the lower portion, and a second pixel corresponding to an end portion of the upper portion, based on luminance values of a plurality of pixels constituting the first image, and
the measuring unit is configured to measure the amount of protrusion, based on the number of pixels arranged between the identified first and second pixels.
